(19) United States
(12) Patent Application Publication
(10) Pub. No.: US 2024/0306368 A1
(43) Pub. Date: Sep. 12, 2024

(54) SEMICONDUCTOR DEVICE AND MANUFACTURING METHOD THEREOF

(71) Applicant: Kioxia Corporation, Tokyo (JP)

(72) Inventors: Takeru MAEDA, Yokkaichi Mie (JP); Kotaro NODA, Yokkaichi Mie (JP); Shosuke FUJII, Kuwana Mie (JP)

(21) Appl. No.: 18/593,988

(22) Filed: Mar. 4, 2024

(30) Foreign Application Priority Data
Mar. 9, 2023 (JP) 2023-036299

(51) Int. Cl. H10B 12/00

(52) U.S. Cl. CPC H10B 12/33; H10B 12/05

(57) ABSTRACT

A semiconductor device includes a semiconductor substrate, a memory capacitor provided on the semiconductor substrate, a first conductor provided above the memory capacitor and extending in a first direction, a second conductor provided above the first conductor and extending in the first direction, an oxide semiconductor layer provided between the first conductor and the second conductor and extending in the first direction, a conductive oxide layer between the second conductor and the oxide semiconductor layer, a first conductive layer between the conductive oxide layer and the second conductor, and an insulating layer in contact with the conductive oxide layer, wherein a portion of the conductive oxide layer is between and aligned with the first insulating layer and the oxide semiconductor layer in the first direction.

### CROSS-REFERENCE TO RELATED APPLICATION(S)

This application is based upon and claims the benefit of priority from Japanese Patent Application No. 2023-036299, filed Mar. 9, 2023, the entire contents of which are incorporated herein by reference.

### FIELD

Embodiments described herein relate generally to a semiconductor device and a manufacturing method thereof.

### BACKGROUND

A semiconductor storage device having a bit line, a word line, and a memory cell connected to the bit line and the word line has been used. Data can be written into and read from the memory cell by selecting the bit line and the word line and applying appropriate voltages to the selected bit line and the selected word line.

### DESCRIPTION OF THE DRAWINGS

FIG. 1 is a circuit diagram of a memory cell array of a semiconductor device.

FIG. 2 is a plan view of the memory cell array of the semiconductor device.

FIG. 3 is a cross-sectional view of the memory cell array of the semiconductor device.

FIG. 4A is a cross-sectional view of a memory cell array of a semiconductor device according to a comparative example.

FIG. 4B is a plan view of the memory cell array of the semiconductor device according to the comparative example.

FIG. 5A is a cross-sectional view of a memory cell array of a semiconductor device according to a first embodiment.

FIG. 5B is a plan view of the memory cell array of the semiconductor device according to the first embodiment.

FIGS. 6A-6E are cross-sectional views of a method for manufacturing the semiconductor device according to the first embodiment.

FIG. 7 is a cross-sectional view of a memory cell array of a semiconductor device according to a second embodiment.

FIG. 8 is a plan view of the memory cell array of the semiconductor device according to the second embodiment.

FIGS. 9A-9H are cross-sectional views of a method for manufacturing the semiconductor device according to the second embodiment.

FIG. 10 is a cross-sectional view of a memory cell array of a semiconductor device according to a third embodiment.

FIG. 11 is a plan view of the memory cell array of the semiconductor device according to the third embodiment.

FIGS. 12A-12H are cross-sectional views of a method for manufacturing the semiconductor device according to the third embodiment.

### DETAILED DESCRIPTION

Embodiments provide a semiconductor device with increased reliability and a manufacturing method thereof.

In general, according to one embodiment, a semiconductor device includes a semiconductor substrate, a memory capacitor provided on the semiconductor substrate, a first conductor provided above the memory capacitor and extending in a first direction, a second conductor provided above the first conductor and extending in the first direction, an oxide semiconductor layer provided between the first conductor and the second conductor and extending in the first direction, a first conductive oxide layer between the second conductor and the oxide semiconductor layer, a conductive layer between the conductive oxide layer and the second conductor, and a first insulating layer in contact with the conductive oxide layer, wherein a portion of the conductive oxide layer is between and aligned with the first insulating layer and the oxide semiconductor layer in the first direction.

Hereinafter, embodiments will be described with reference to the drawings. The relationship between the thickness and the plane dimension of each element shown in the drawings, the ratio of the thickness of each element, and the like may be different from the actual relationship, ratio, and the like. The up-down direction may be different from the up-down direction according to gravity. Further, in the embodiments, substantially the same elements will be given the same reference signs, and the description thereof will be omitted as appropriate.

In the present specification, the term “connection” includes not only a physical connection but also an electrical connection, and includes not only a direct connection but also an indirect connection, unless otherwise specified.

In the following description, a direction that is perpendicular to a semiconductor substrate extending in an XY plane is a Z direction, a direction orthogonal to the Z direction and is an extension direction of a word line WL is an X direction, and a direction that is perpendicular to the Z direction and the X direction and is an extension direction of a bit line BL is a Y direction.

In addition, in the following description, the memory cell array of the semiconductor device may be simply referred to as the semiconductor device.

The semiconductor device of the embodiment is a dynamic random access memory (DRAM) having a memory cell array.

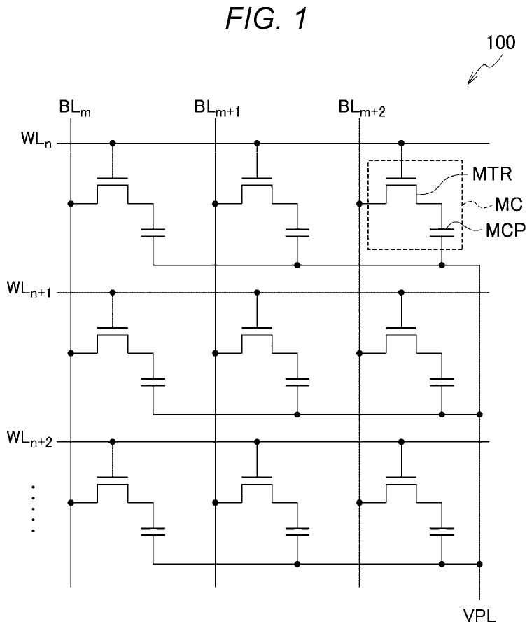

FIG. 1 is a circuit diagram illustrating a circuit configuration of a memory cell array 100 of the semiconductor device. FIG. 1 shows a plurality of memory cells MC, a plurality of word lines WL (word line WLn, word line WLn+1, and word line WLn+2, n is an integer), a plurality of bit lines BL (bit line BLm, bit line BLm+1, and bit line BLm+2, m is an integer), and a power line VPL.

The plurality of memory cells MC are arranged in a matrix configuration to form a memory cell array. Each memory cell MC includes a memory transistor MTR which is a field effect transistor (FET), and a memory capacitor MCP.

The field effect transistor has a gate, a source, and a drain. The field effect transistor may further have a back gate. Since the source and the drain are interchangeable with each other depending on the structure and the operating condition of the transistor, the description provided herein does not specify which is the source or the drain. Therefore, unless otherwise specified, one terminal the source or the drain, and the other terminal is the other of the source or the drain.

The gate of the memory transistor MTR is connected to the corresponding word line WL, and one of the source or the drain is connected to the corresponding bit line BL. The word line WL is connected to, for example, a row decoder. The bit line BL is connected to, for example, a sense amplifier. A first electrode of the memory capacitor MCP is connected to the other of the source or the drain of the memory transistor MTR, and a second electrode is connected to the power line VPL that supplies a specific voltage. The power line VPL is connected to, for example, a power supply circuit. The memory cell MC can store charges from the bit line BL in the memory capacitor MCP by switching of the memory transistor MTR using the word line WL. The number of the plurality of memory cells MC is not limited to the number shown in FIG. 1.

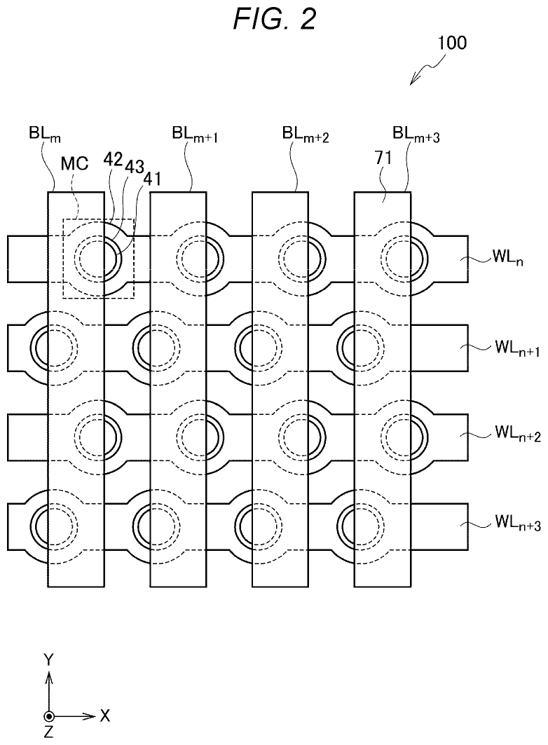

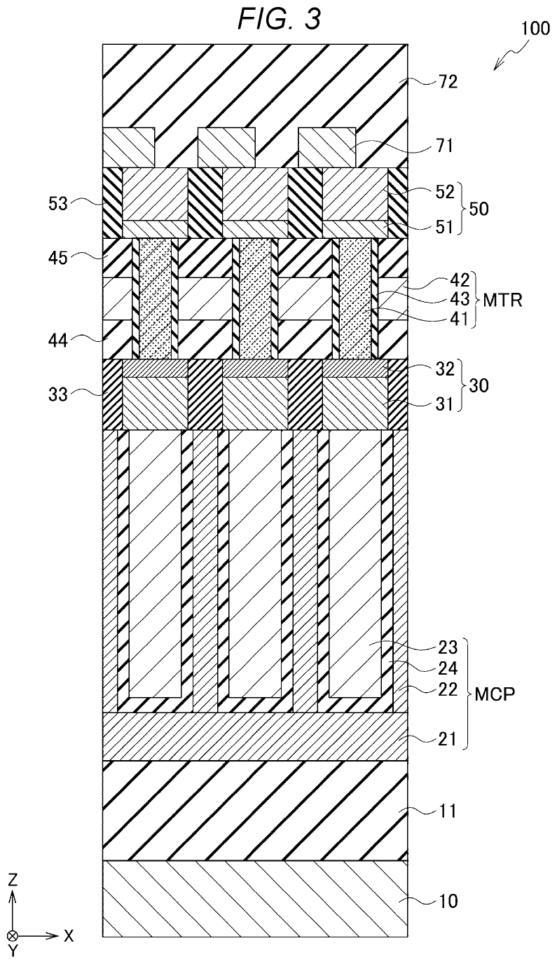

FIG. 2 is a plan view illustrating the structure of the memory cell array 100 of the semiconductor device. FIG. 3 is a cross-sectional view illustrating the structure of the memory cell array 100 of the semiconductor device.

As shown in FIG. 3, the memory cell array 100 includes a conductor 21, a conductive layer 22, an electrical conductor 23, an insulator 24, a conductive layer 31, a conductive oxide layer 32, an oxide semiconductor layer 41, a conductive layer 42, an insulating film 43, a conductive oxide layer 51, a conductive layer 52, and a conductive layer 71. For convenience, FIG. 2 shows the oxide semiconductor layer 41, the conductive layer 42, the insulating film 43, and the conductive layer 71, and other elements are not shown.

The memory transistor MTR and the memory capacitor MCP are provided above an insulating layer 11 on a semiconductor substrate 10 as shown in FIG. 3. Peripheral circuits such as the row decoder, the sense amplifier, and the power supply circuit are formed on the semiconductor substrate 10. The peripheral circuit has, for example, a field effect transistor such as a P-channel field effect transistor (Pch-FET) or an N-channel field effect transistor (Nch-FET), and a complementary field effect transistor (CMOSFET). The field effect transistor can be formed using the semiconductor substrate 10, e.g., a single crystal silicon substrate, and the Pch-FET and the Nch-FET have a channel region, a source region, and a drain region in the semiconductor substrate 10. Note that the semiconductor substrate 10 may have a P-type conductive type. The insulating layer 11 is provided on the semiconductor substrate 10 and contains, for example, silicon (Si) and oxygen (O) or nitrogen (N). The insulating layer 11 may be a stacked film.

The conductor 21, the conductive layer 22, the electrical conductor 23, and the insulator 24 form the memory capacitor MCP. Here, the conductor 21 is connected to the power line VPL. The conductor 21 can be disposed as a common electrode in the memory cell array. The conductive layer 22 is in contact with the conductor 21 and forms one electrode of the memory capacitor. The electrical conductor 23 forms the other electrode of the memory capacitor and is connected to the conductor 30 of each memory transistor MTR. The memory capacitor MCP is a three-dimensional capacitor such as a so-called pillar-type capacitor or a cylinder-type capacitor.

The conductor 21 is provided above the semiconductor substrate 10 with the insulating layer 11 sandwiched therebetween. The conductive layer 22 is provided on a part of the conductor 21. The conductor 21 and the conductive layer 22 form the second electrode of the memory capacitor MCP. The conductor 21 extends to overlap the plurality of electrical conductors 23 when viewed in the Z direction. The conductor 21 is also referred to as a plate electrode. The electrical conductor 23 is provided above the conductor 21 with the insulator 24 sandwiched therebetween, extends in the Z direction, and forms the first electrode of the memory capacitor MCP. The insulator 24 is also provided between the conductor 21 and the conductive layer 22 and the electrical conductor 23 to form a dielectric of the memory capacitor MCP.

The conductor 21 and the conductive layer 22 contain, for example, a material such as tungsten (W) or titanium nitride (TiN). The electrical conductor 23 contains, for example, a material such as tungsten (W), titanium nitride (TiN), or amorphous silicon. The insulator 24 contains, for example, a material such as hafnium oxide (HfOx), zirconium oxide (ZrOx), or aluminum oxide (AlOx).

The conductive layer 31 is provided on the electrical conductor 23 and is electrically connected to the electrical conductor 23. The conductive layer 31 contains, for example, copper (Cu). The conductive layer 31 is optional and does not necessarily have to be formed.

The conductive oxide layer 32 is provided on the conductive layer 31. The conductive oxide layer 32 contains, for example, a metal oxide such as indium (In)-tin (Sn)-oxide (ITO).

The conductive layer 31 and the conductive oxide layer 32 form the conductor 30. A plurality of conductors 30 are provided with respect to the plurality of electrical conductors 23. An insulating layer 33 is formed between the plurality of conductors 30. The insulating layer 33 contains, for example, silicon (Si) and oxygen (O) or nitrogen (N).

The oxide semiconductor layer 41, the conductive layer 42, and the insulating film 43 form the memory transistor MTR. The memory transistor MTR is, for example, an N-channel field effect transistor. The memory transistor MTR is provided above the memory capacitor MCP. A plurality of memory transistors MTR are provided corresponding to the plurality of memory capacitors MCP. An insulating layer 44 and an insulating layer 45 are formed between the plurality of memory transistors MTR. The insulating layer 44 and the insulating layer 45 contain, for example, silicon (Si) and oxygen (O) or nitrogen (N).

The oxide semiconductor layer 41 is, for example, a columnar body extending in the Z direction. The oxide semiconductor layer 41 penetrates the conductive layer 42 in the Z direction. The oxide semiconductor layer 41 forms a channel of the memory transistor MTR. The oxide semiconductor layer 41 contains, for example, indium (In). The oxide semiconductor layer 41 contains, for example, indium oxide and gallium oxide, indium oxide and zinc oxide, or indium oxide and tin oxide. As an example, the oxide semiconductor layer 41 contains an oxide including indium, gallium, and zinc (indium-gallium-zinc-oxide), so-called IGZO (InGaZnO). The oxide semiconductor layer 41 may have an amorphous structure or may have a crystal structure by a heat treatment.

One end of the oxide semiconductor layer 41 in the Z direction is connected to the conductive layer 31 via the conductive oxide layer 32 and functions as the other of the source or the drain of the memory transistor MTR. The conductive oxide layer 32 is provided between the electrical conductor 23 of the memory capacitor MCP and the oxide semiconductor layer 41 of the memory transistor MTR, and functions as the other of the source electrode or the drain electrode of the memory transistor MTR. The conductive oxide layer 32 contains a metal oxide in the same manner as the oxide semiconductor layer 41 of the memory transistor MTR, and thus the connection resistance between the memory transistor MTR and the memory capacitor MCP can be reduced.

The conductive layer 42 includes a portion facing the oxide semiconductor layer 41 with the insulating film 43 sandwiched in the XY plane. The conductive layer 42 surrounds the oxide semiconductor layer 41 and the insulating film 43 in the XY plane. The conductive layer 42 forms the gate electrode of the memory transistor MTR and forms the word line WL as wiring. The conductive layer 42 contains, for example, a metal, a metal compound, or a semiconductor. The conductive layer 42 contains, for example, at least one material selected from the group consisting of tungsten (W), titanium (Ti), titanium nitride (TiN), molybdenum (Mo), cobalt (Co), and ruthenium (Ru).

In FIG. 2, a region of the conductive layer 42 that does not overlap the memory transistor MTR in the Y direction is narrower than a region that overlaps with the memory transistor MTR when viewed in the Y direction. However, the present disclosure is not limited thereto, and the conductive layer 42 may have a constant width in the Y direction.

The plurality of conductive layers 42 extend in the X direction and are disposed in parallel with each other, as shown in FIG. 2. Each of the conductive layers 42 overlaps and is connected to the plurality of memory cells MC in the X direction.

The insulating film 43 is provided between the oxide semiconductor layer 41 and the conductive layer 42 in the XY plane. The insulating film 43 forms a gate insulating film of the memory transistor MTR. The insulating film 43 contains, for example, silicon (Si) and oxygen (O) or nitrogen (N). The insulating film 43 may be a stacked film of a plurality of insulating films.

The memory transistor MTR has a so-called surrounding gate transistor (SGT) structure in which a gate electrode surrounds a channel. Thereby, the area of the semiconductor device can be reduced by the SGT structure.

The electric field effect transistor having a channel layer including an oxide semiconductor has a lower off-leakage current than the electric field effect transistor provided on the semiconductor substrate 10. Therefore, for example, since the data stored in the memory cell MC can be stored for a long time, the number of times of the refresh operation can be reduced. In addition, since the field effect transistor having the channel layer including the oxide semiconductor can be formed by a low-temperature process, thermal stress applied to the memory capacitor MCP can be reduced.

The conductive oxide layer 51 is provided on the oxide semiconductor layer 41. The conductive oxide layer 51 contains, for example, a metal oxide such as indium-tin-oxide (ITO).

The conductive layer 52 is provided on the conductive oxide layer 51 and is electrically connected to the conductive oxide layer 51. The conductive layer 52 contains, for example, copper (Cu).

The conductive oxide layer 51 and the conductive layer 52 form a conductor 50. The conductive layer 52 is a conductive layer for electrically connecting the memory transistor MTR and the bit line BL, and is a main portion of the bit line BL. The conductive oxide layer 51 is a layer for ensuring a favorable electrical connection between the oxide semiconductor layer 41 and the conductive layer 52, and is formed of an electrode material containing an oxide. The conductive layer 52 is electrically connected to the conductive oxide layer 51 and is integrated to form the conductor 50. Usually, an adhesion layer is provided between the conductive oxide layer 51 and the conductive layer 52, but is not shown in FIG. 3. The conductor 50 is electrically connected to the sense amplifier via the bit line BL. The conductor 50 has a function as a conductive pad for connecting the memory transistor MTR and the bit line BL, for example. The conductor 50 is also referred to as a landing pad (LP). A plurality of conductors 50 are provided corresponding to the plurality of memory transistors MTR. An insulating layer 53 is formed between the plurality of conductors 50. The insulating layer 53 contains, for example, silicon (Si) and oxygen (O) or nitrogen (N).

The other end of the oxide semiconductor layer 41 in the Z direction is connected to the conductive layer 52 via the conductive oxide layer 51 and functions as one of the source or the drain of the memory transistor MTR. The conductive oxide layer 51 functions as one of the source electrode or the drain electrode of the memory transistor MTR. The conductive oxide layer 51 contains a metal oxide in the same manner as the oxide semiconductor layer 41 of the memory transistor MTR, and thus the connection resistance between the memory transistor MTR and the bit line BL can be reduced.

The conductive layer 71 is provided on the conductive layer 52 and is connected to the conductor 50. The conductive layer 71 forms the bit line BL as wiring. An insulating layer 72 is formed between the plurality of conductive layers 71. The insulating layer 72 contains, for example, silicon and oxygen or nitrogen.

The plurality of conductive layers 71 (bit lines BL) extend in the Y direction and are disposed in parallel with each other, as shown in FIG. 2. Each of the conductive layers 71 overlaps and is connected to the plurality of memory cells MC when viewed in the Z direction.

The plurality of memory cells MC may be arranged in a staggered manner in the XY plane as shown in FIG. 2. The memory cell MC connected to one of the plurality of word lines WL is shifted in the X direction with respect to the memory cell MC connected to the adjacent word line WL. As a result, the integration degree of the memory cell MC can be increased.

The insulating film 43 that serves as the gate insulating film of the memory transistor MTR is formed using an oxide film such as a silicon oxide film, and it is preferable to form a nitride film such as a silicon nitride film between the silicon oxide film and the word line (gate electrode) in order to reduce diffusion of a metal element such as tungsten from the word line (gate electrode) into the silicon oxide film.

### Comparative Example

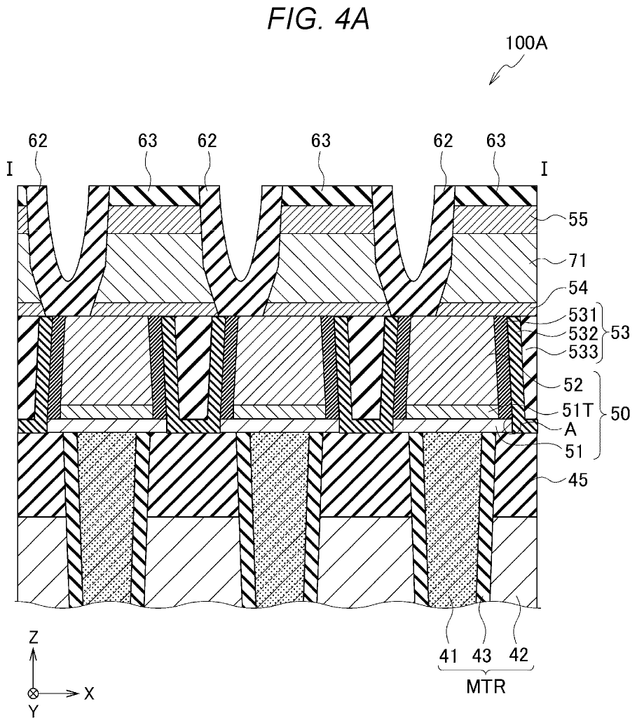

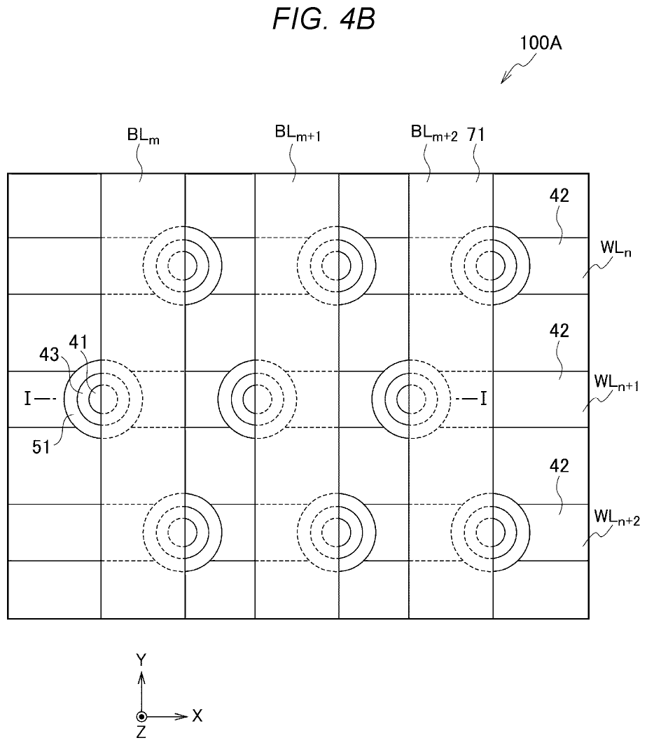

FIG. 4A is a cross-sectional view of a memory cell array 100A of a semiconductor device according to the comparative example. FIG. 4B is a plan view of the memory cell array 100A of the semiconductor device according to the comparative example. FIG. 4A shows a cross-sectional structure taken along the line I-I of FIG. 4B.

In the semiconductor device according to the comparative example, the conductive oxide layer 51 is provided on the oxide semiconductor layer 41. Further, a conductive layer 51T is provided on the conductive oxide layer 51. The conductive oxide layer 51 is also referred to as a top electrode (TE). The conductive layer 51T is formed of, for example, titanium nitride (TiN), titanium oxide (TiO), or titanium oxynitride (TiON).

The conductive oxide layer 51, the conductive layer 51T, and the conductive layer 52 form the conductor 50. The conductive layer 51T can reduce the connection resistance between the conductive oxide layer 51 and the conductive layer 52.

In the semiconductor device according to the comparative example, an oxygen (O₂) annealing treatment for supplying oxygen to the oxide semiconductor layer 41 formed of IGZO is performed after the conductive oxide layer 51 is formed. For example, since the conductive oxide layer 51 containing a metal oxide such as ITO is a metal material through which oxygen can be transmitted, the oxygen can be supplied to the IGZO channel of the oxide semiconductor layer 41 through the conductive oxide layer 51. The threshold value of the memory transistor MTR can be increased by supplying oxygen to the IGZO channel. Therefore, the oxygen (O₂) annealing treatment is intended to increase the threshold value of the memory transistor MTR.

It is assumed that oxygen is removed from the IGZO channel by a heat load (particularly, a CVD step (approximately 250° C. to 450° C.)) in steps after the formation of the IGZO channel. Therefore, it is desirable that the oxygen supply to the IGZO channel is performed in the later step as much as possible.

In the semiconductor device according to the comparative example, in a landing pad (LP) processing step of processing the conductive layer 52 to form a recessed portion, the conductive layer 51T formed of TiN and the conductive oxide layer 51 formed of ITO are removed by etching, and then oxygen is supplied from an exposed side wall portion (the portion A in FIG. 4A) of the conductive oxide layer 51. The exposed area of the side wall of the conductive oxide layer 51 depends on the diameter and the height of the conductive oxide layer 51. Usually, the diameter of the conductive oxide layer 51 is as small as about 10 to 30 nm, and the thickness thereof is as thin as about 5 to 10 nm. Therefore, the exposed area of the side wall of the conductive oxide layer 51 is also small. Therefore, when oxygen is supplied to the oxide semiconductor layer 41 via the side wall of the conductive oxide layer 51, the oxygen (O₂) annealing treatment for a long time is required. In addition, when the supply of oxygen is insufficient, it is difficult to control the threshold value of the memory transistor MTR, and the reliability of the memory operation is reduced.

Insulating layers 53 (insulating layers 531, 532, and 533) are formed on the side wall portions of the conductive layer 52, which is processed into the recessed shape, the conductive layer 51T, and the conductive oxide layer 51. The insulating layer 531 and the insulating layer 532 are formed of an oxide film, a nitride film, or the like, and are also referred to as a liner insulating film. The insulating layer 533 is formed of a silicon oxide film or the like and is also referred to as a gap filling film.

In the semiconductor device according to the comparative example, the conductive layer 54, the conductive layer 71, the conductive layer 55, and the insulating layer 63 are formed on the conductive layer 52. Thereafter, the conductive layer 54, the conductive layer 71, the conductive layer 55, and the insulating layer 63 are removed to separate the conductive layers 54 from each other, the conductive layers 71 from each other, and the conductive layers 55 from each other, and an insulating layer 62 is formed in the separated groove.

### First Embodiment

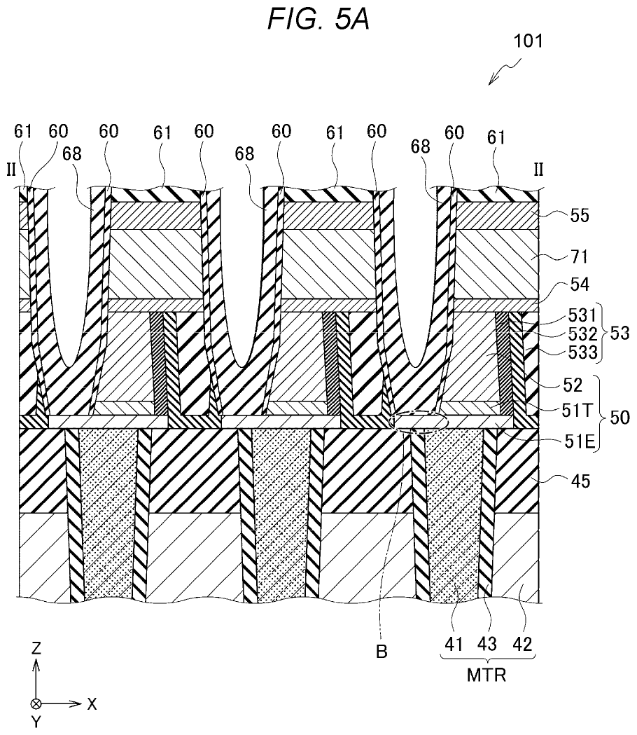

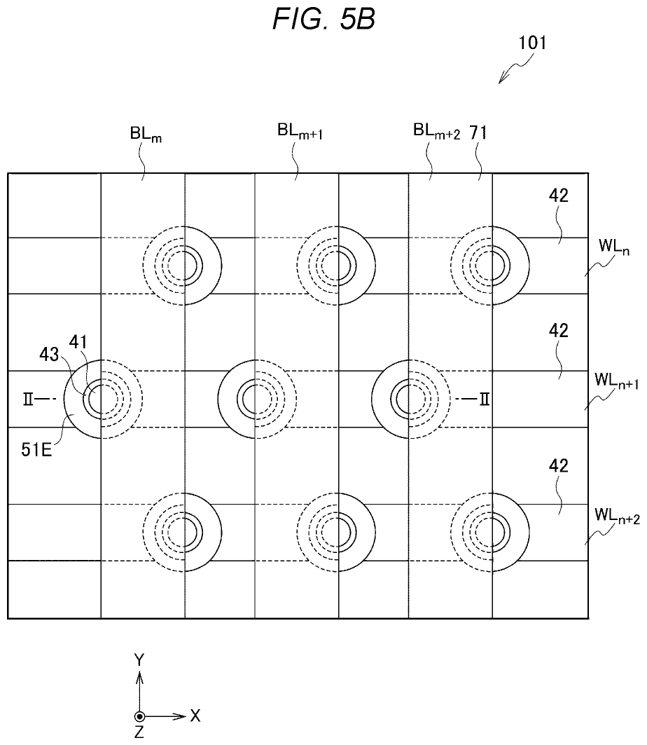

FIG. 5A is a cross-sectional view of a memory cell array 101 of the semiconductor device according to the first embodiment. FIG. 5B is a plan view of the memory cell array 101 of the semiconductor device according to the first embodiment. FIG. 5A shows a cross-sectional structure taken along the line II-II of FIG. 5B.

As in the structure shown in FIG. 3, the semiconductor device according to the first embodiment includes the first conductor 30, the second conductor 50, the oxide semiconductor layer 41 provided between the first conductor and the second conductor and extending in the Y direction, the conductive layer 42 extending in the X direction intersecting the Y direction and surrounding the oxide semiconductor layer 41, and the insulating film 43 provided between the oxide semiconductor layer 41 and the conductive layer 42 and being an oxide film in contact with the conductive layer 42.

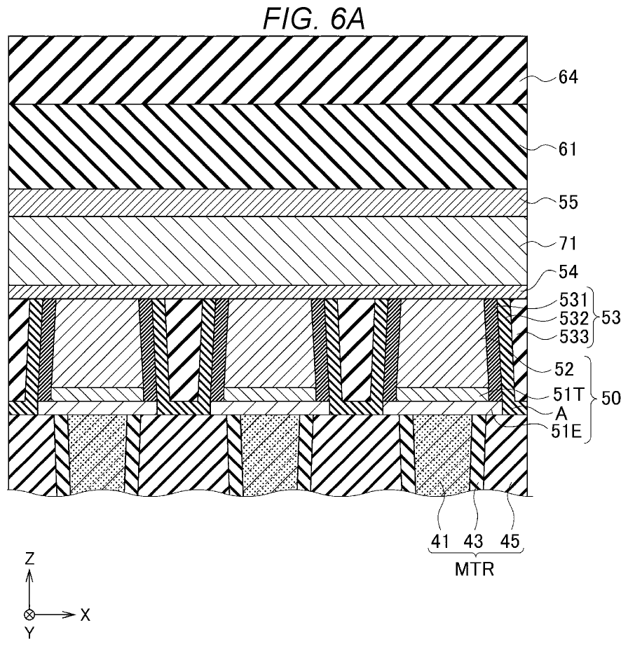

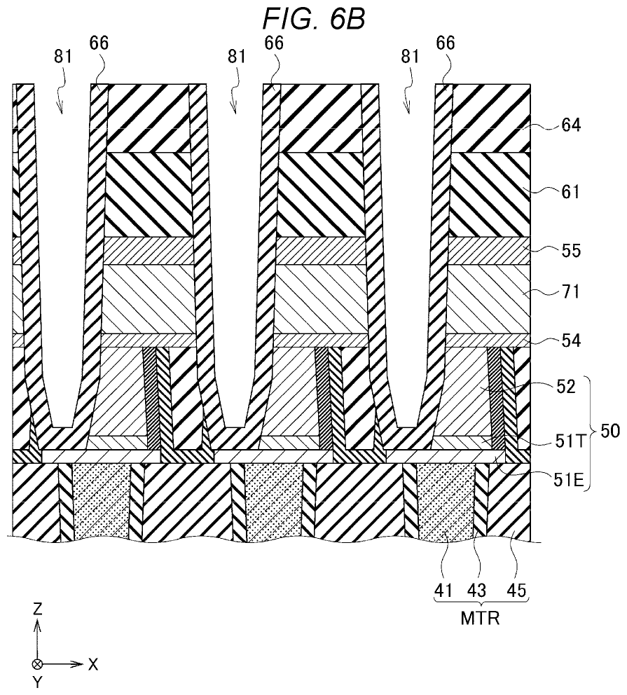

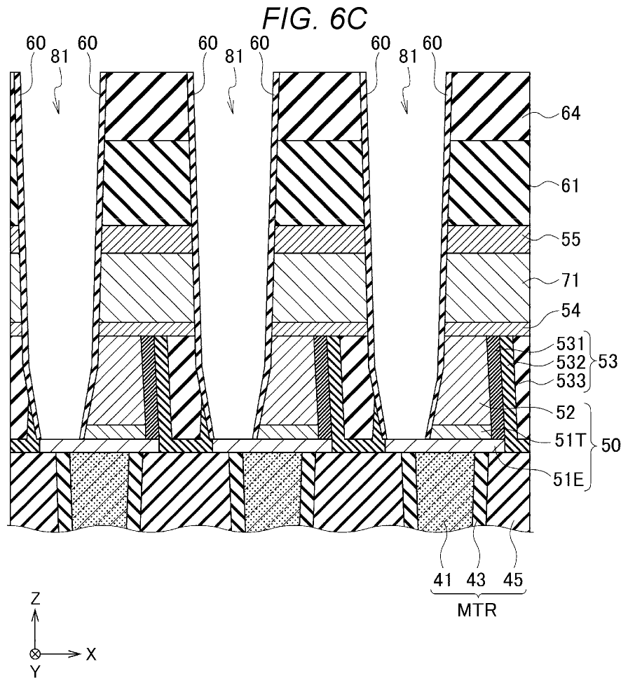

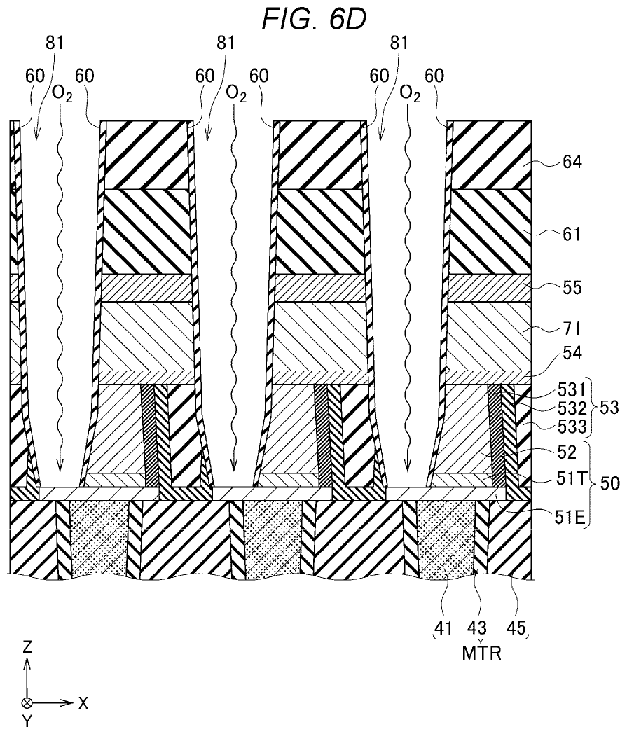

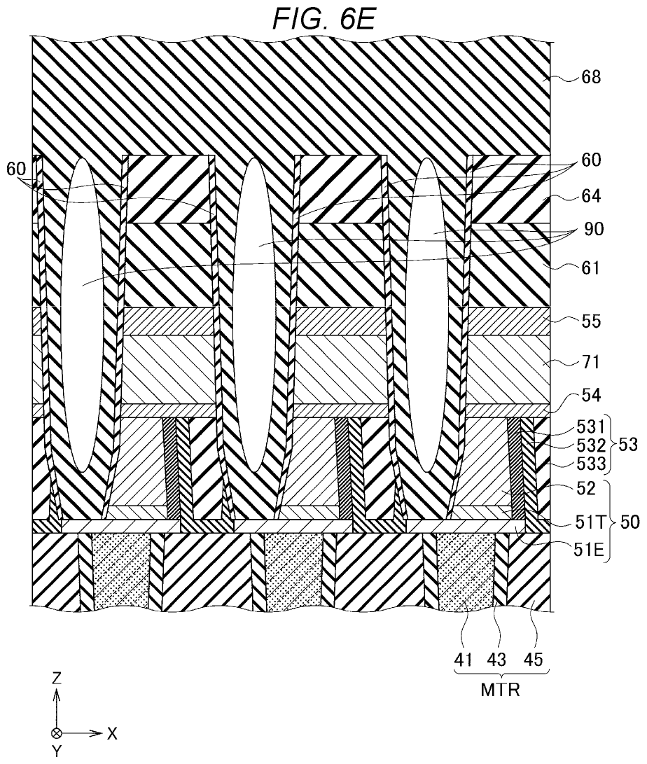

Further, the semiconductor device according to the first embodiment includes the semiconductor substrate 10, the memory capacitor MCP provided above the semiconductor substrate 10, and the memory transistor MTR (also shown in FIG. 5A) provided above the memory capacitor MCP, the first conductor 30 provided on the memory capacitor MCP and extending in the Y direction, the second conductor 50 provided on the memory transistor MTR and extending in the Y direction, and the oxide semiconductor layer 41 provided between the first conductor 30 and the second conductor 50 and extending in the Y direction. Further, as shown in FIGS. 5A and 5B, the semiconductor device according to the first embodiment includes a conductive oxide layer 51E provided on the memory transistor MTR and connected to the oxide semiconductor layer 41, a conductive layer 71 connected to the conductive oxide layer 51E and serving as the bit line BL, and an insulating layer 68 provided between the bit lines BL. The bit line BL includes three layers of the main conductive layer 71, a barrier metal conductive layer 54, and a conductive layer 55. In addition, the landing pad (LP) includes three layers of a main conductive layer 52, a barrier metal conductive layer 51T, and a conductive oxide layer 51E. Here, the bottom portion of the insulating layer 68 between the bit lines BL is in contact with the conductive oxide layer 51E. In FIG. 5A, the insulating layer 68, the insulating layer 64, a part of the insulating layer 60, and a part of the insulating layer 61 in the structure of FIG. 6E are omitted.

In addition, the semiconductor device according to the first embodiment includes the conductive layer 42 that extends in the X direction intersecting the Y direction and surrounds the oxide semiconductor layer 41, and the insulating film 43 that is provided between the oxide semiconductor layer 41 and the conductive layer 42 and is an oxide film in contact with the conductive layer 42.

In the semiconductor device according to the first embodiment, as shown in FIG. 5A, the conductive oxide layer 51E is provided on the oxide semiconductor layer 41. Further, the conductive layer 51T is provided on the conductive oxide layer 51E. The conductive oxide layer 51E, the conductive layer 51T, and the conductive layer 52 form the conductor 50.

In the semiconductor device according to the first embodiment, the conductive layer 54, the conductive layer 71, the conductive layer 55, and the insulating layer 63 are formed on the conductive layer 52. Thereafter, the conductive layer 55, the conductive layer 71, the conductive layer 54, the conductive layer 52, the conductive layer 51T, and a part of the insulating layer 53 are removed to expose the surface of the conductive oxide layer 51E.

In the structure of the semiconductor device according to the first embodiment, the conductive layers 54 are separated from each other, the conductive layers 71 are separated from each other, and the conductive layers 55 are separated from each other, and the surface of the conductive oxide layer 51E is exposed at the bottom portion of a separated groove 81 (see FIG. 6B). Therefore, as shown in FIG. 5A, it is possible to widen an area of a B portion on the surface of the conductive oxide layer 51E that is exposed by the separated groove 81.

In the structure of the semiconductor device according to the first embodiment, oxygen is supplied from between the conductive layers 54, between the conductive layers 71, and between the conductive layers 55, and thus oxygen can be supplied to the oxide semiconductor layer 41 of the IGZO channel via the exposed surface of the conductive oxide layer 51E.

In the semiconductor device according to the first embodiment, after the surface of the conductive oxide layer 51E is exposed, the oxygen (O₂) annealing treatment is performed for the purpose of supplying oxygen to the oxide semiconductor layer 41. Since the conductive oxide layer 51E containing a metal oxide is a metal material through which oxygen can be transmitted, oxygen can be supplied to the IGZO channel of the oxide semiconductor layer 41 via the conductive oxide layer 51E. The threshold value of the memory transistor MTR can be increased by supplying oxygen to the IGZO channel.

In the structure of the semiconductor device according to the first embodiment, oxygen can be supplied after separation formation between the conductive layers 54, between the conductive layers 71, and between the conductive layers 55. Therefore, after the formation of the IGZO channel, the oxygen deficiency due to the heat load to the IGZO until the separation formation between the conductive layers 54, between the conductive layers 71, and between the conductive layers 55 can be reduced.

In the structure of the semiconductor device according to the first embodiment, the conductive layers 54 are separated from each other, the conductive layers 71 serving as the bit lines BL are separated from each other, and the conductive layers 55 are separated from each other, the insulating layer 60 such as a nitride film called a liner insulating film is formed on the side wall portion of the separated groove 81, and the insulating layer 68 is formed on the bottom portion of the groove 81 and on the insulating layer 60.

The semiconductor device according to the first embodiment has a structure in which oxygen can be efficiently supplied to IGZO because of the exposed surface of the conductive oxide layer 51E described above. In this case, the exposed surface area of the conductive oxide layer 51E is improved by about 1.5 to 2 times as compared to the area through which oxygen can be supplied in the comparative example, depending on the diameter and the height of the conductive oxide layer 51E.

The insulating film 43 contains at least one element selected from the group consisting of silicon (Si), aluminum (Al), hafnium (Hf), zirconium (Zr), lanthanum (La), niobium (Nb), yttrium (Y), tantalum (Ta), vanadium (V), and magnesium (Mg), and oxygen.

The insulating layer 60 and the insulating layer 68 preferably contain at least one material selected from the group consisting of aluminum oxide (AlOx), zirconium oxide (ZrOx), silicon nitride (SiNx), and silicon oxide (SiOx), and have a barrier property to oxygen, hydrogen, and water.

The conductive layer 52 forming the landing pad (LP) contains at least one material selected from the group consisting of tungsten (W), copper (Cu), titanium (Ti), titanium nitride (TiN), molybdenum (Mo), cobalt (Co), and ruthenium (Ru).

The conductive layer 71 serving as the bit line BL is formed by, for example, CVD of tungsten (W), and the formation temperature range is, for example, about 250° C. to 450° C.

In addition, in the semiconductor device according to the first embodiment, as shown in FIGS. 5A and 5B, the conductive layer 52 forming the landing pad (LP) is thicker than the conductive oxide layer 51E. The reason for this is that it is necessary to allocate the clearance between the conductive oxide layer 51E connected to the adjacent bit line BL and its own bit line BL.

TIN, TiO, or TiON of the conductive layer 51T forming the landing pad (LP) has a function as an adhesive layer that connects the conductive oxide layer 51E made of ITO and the conductive layer 52 made of W to each other because of poor adhesion therebetween. In addition, TiN of the conductive layer 54 is a barrier metal and has a function of preventing element diffusion from the conductive layer 71 of the bit line BL and preventing a reaction between the conductive layer 71 of the bit line BL and the upper and lower oxide films and ensuring adhesion.

In the semiconductor device according to the first embodiment, a part of the insulating layer 68 between the adjacent bit lines BL is in contact with the conductive oxide layer 51E of the top electrode (TE).

In the semiconductor device according to the first embodiment, since oxygen can be supplied after the bit line BL is formed, oxygen loss due to the temperature of the BL forming process is avoided.

The semiconductor device according to the first embodiment supplies oxygen to the oxide semiconductor layer 41 of the memory transistor MTR via the conductive oxide layer 51E from between the BLs in an oxygen gas atmosphere.

In addition, in the semiconductor device according to the first embodiment, the side wall of the BL is protected by the insulating layer 60, and the insulating layer 60 in contact with a certain side wall of the BL is not in contact with the side wall of the adjacent BL. That is, the insulating layer 60 between the BLs is removed at the bottom portion between the BLs.

In addition, in the semiconductor device according to the first embodiment, the insulating layer 60 is removed down to the conductive oxide layer 51E, which is TE·ITO during the reactive ion etching (RIE) of the BL, the insulating layer 60 is formed on the BL side wall, the lower portion of the insulating layer 60 is etched back (EB: Etch Back) to expose the conductive oxide layer 51E, and oxygen is supplied from the gap between the BLs. Since oxygen can be supplied after the formation of the BL, the influence by oxygen deficiency from the oxide semiconductor layer 41 due to the temperature of the BL formation process or the like is avoided.

### Manufacturing Method in First Embodiment

Next, the method for manufacturing the semiconductor device according to the first embodiment will be described with reference to FIGS. 6A to 6E.

First, as shown in FIG. 6A, the conductive oxide layer 51E, the conductive layer 51T, and the conductive layer 52 are formed on the memory transistor MTR, the landing pad (LP) is patterned by a lithography step, the conductive layer 52 and the conductive layer 51T are processed by RIE, the conductive oxide layer 51E is processed by RIE while the side walls of the conductive layer 52 and the conductive layer 51T are protected by a liner film 531, oxygen is supplied, and then a liner film 532 is formed and a gap filling film 533 is embedded. Thereafter, the surface is flattened by polishing up to the upper end of the conductive layer 52 using a chemical mechanical polishing (CMP) technique. Next, the conductive layer 54, the conductive layer 71, the conductive layer 55, the insulating layer 61, and the insulating layer 64 are sequentially formed. Here, the conductive layer 55 is formed of, for example, TiN or the like, and the insulating layer 64 is formed of a nitride film or the like. The insulating layer 61 is a silicon oxide film or the like formed by a plasma CVD method using monosilane (SiH₄) as a material gas. The step of forming the insulating layer 64 may be omitted.

Next, as shown in FIG. 6B, the bit line BL is patterned by the lithography step, the insulating layer 64, the insulating layer 61, the conductive layer 55, the conductive layer 71, the conductive layer 54, the conductive layer 52, the conductive layer 51T, and the liner films 531 and 532 and the gap filling film 533 are removed by RIE or the like, and a part of the surface of the conductive oxide layer 51E is exposed. Here, the conductive layer 71 serving as the bit lines BL, the conductive layer 55, and the conductive layer 54 are separated. Furthermore, the insulating layer 66 serving as a liner film is formed in the groove 81 formed by RIE or the like.

Next, as shown in FIG. 6C, the lower portion of the insulating layer 66 is etched until the insulating layer 66 at the bottom portion of the groove 81 is removed to expose the conductive oxide layer 51E. As a result, a part of the surface of the conductive oxide layer 51E is exposed. With this step, when the lower portion of the insulating layer 66 is etched, the side wall of the insulating layer 66 may also be thinned and become, for example, the insulating layer 60 in this case.

Next, as shown in FIG. 6D, oxygen (O₂) is supplied to the oxide semiconductor layer 41 provided above the memory transistor MTR via the conductive oxide layer 51E in an oxygen atmosphere. At this time, since the side wall portion of the groove 81 is protected by the insulating layer 60 such as a nitride film, the conductive layer 55, the conductive layer 71, the conductive layer 54, the conductive layer 52, or the conductive layer 51T are not affected by oxidation due to oxygen supply annealing.

Next, as shown in FIG. 6E, the insulating layer 68 is formed by CVD or the like. At the time of forming the insulating layer 68, the interconnect capacitance of the bit line BL can be reduced by forming an air gap 90. The insulating layer 68 is embedded in the groove 81 after the supply of oxygen (O₂), so that oxygen (O₂) can be confined in the oxide semiconductor layer 41.

### Effects of First Embodiment

According to the first embodiment, it is possible to provide a semiconductor device and a manufacturing method thereof, in which the exposure area to the supply of oxygen can be increased, so that the supply of oxygen can be stably performed, and the decrease in reliability can be reduced.

### Second Embodiment

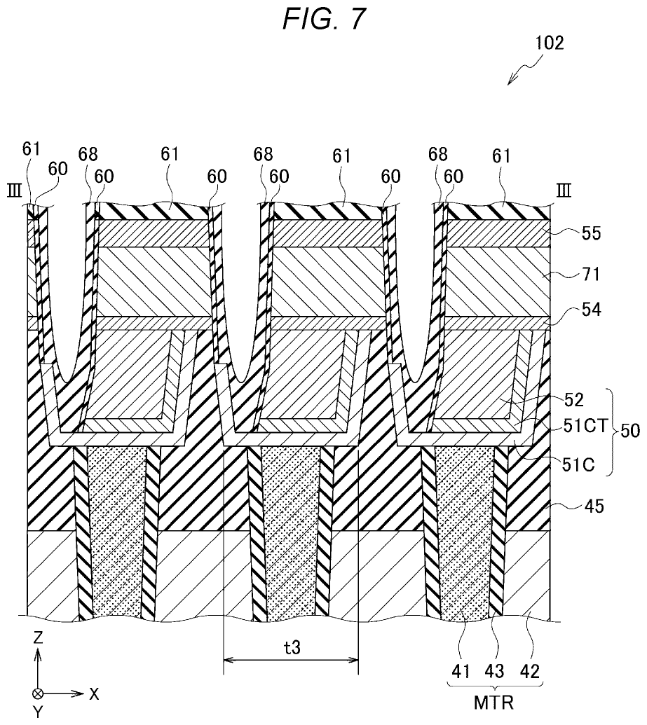

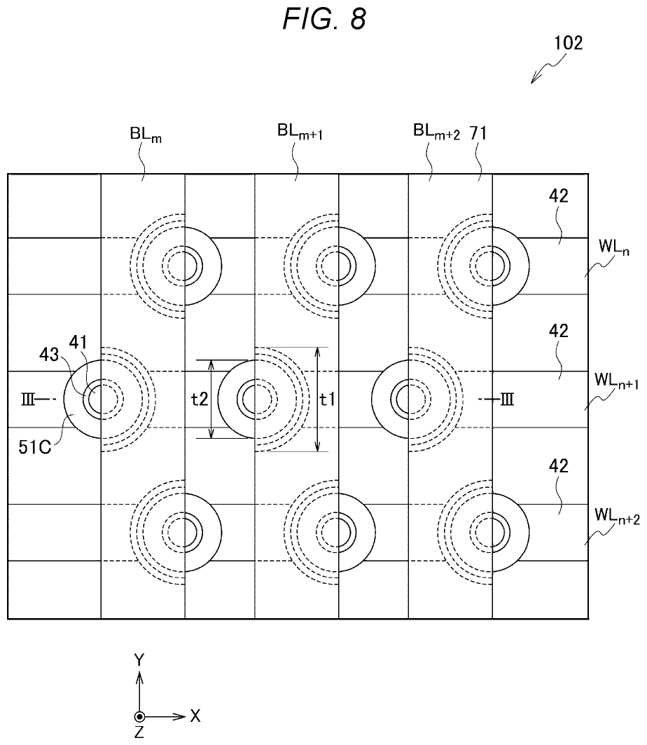

FIG. 7 is a cross-sectional view of a memory cell array 102 of the semiconductor device according to the second embodiment. FIG. 8 is a plan view of the memory cell array 102 of the semiconductor device according to the second embodiment. FIG. 7 shows a cross-sectional structure taken along the line III-III of FIG. 8.

As in the structure shown in FIG. 3, the semiconductor device according to the second embodiment includes the first conductor 30, the second conductor 50, the oxide semiconductor layer 41 provided between the first conductor 30 and the second conductor 50 and extending in the Y direction, the conductive layer 42 extending in the X direction intersecting the Y direction and surrounding the oxide semiconductor layer 41, and the insulating film 43 provided between the oxide semiconductor layer 41 and the conductive layer 42 and being an oxide film in contact with the conductive layer 42.

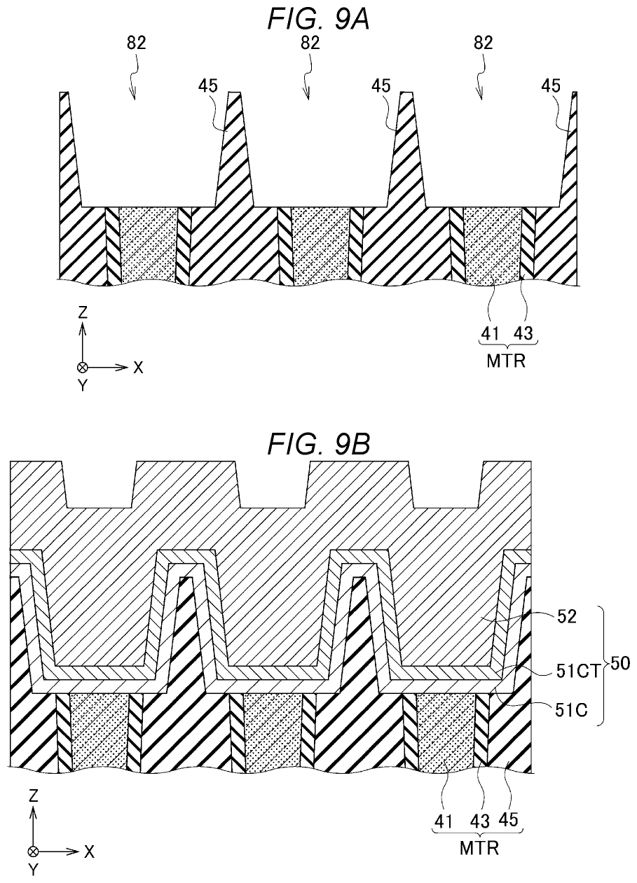

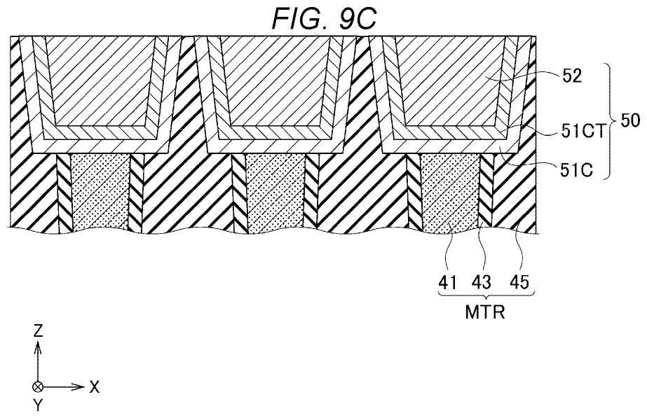

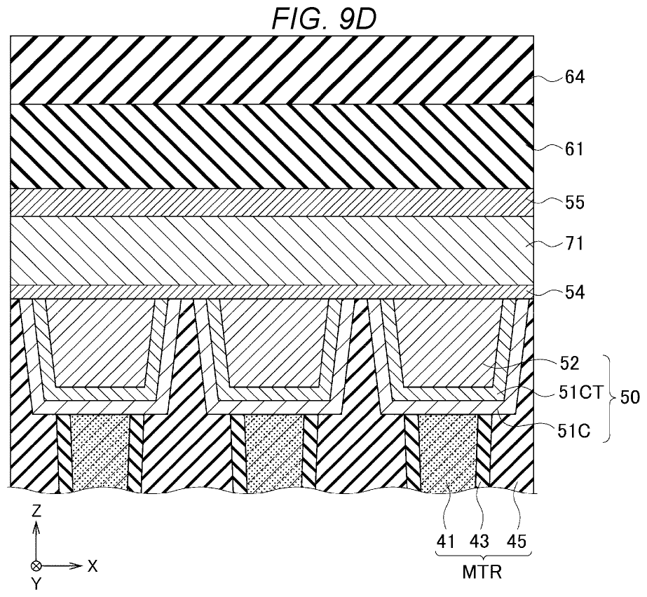

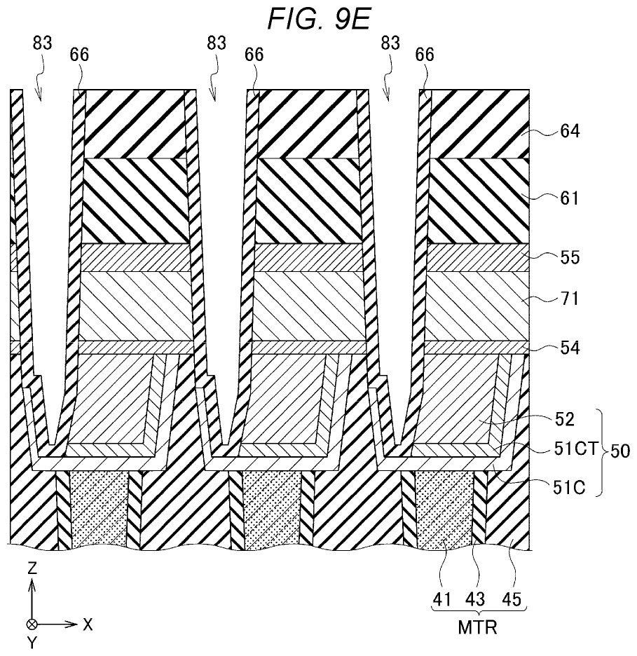

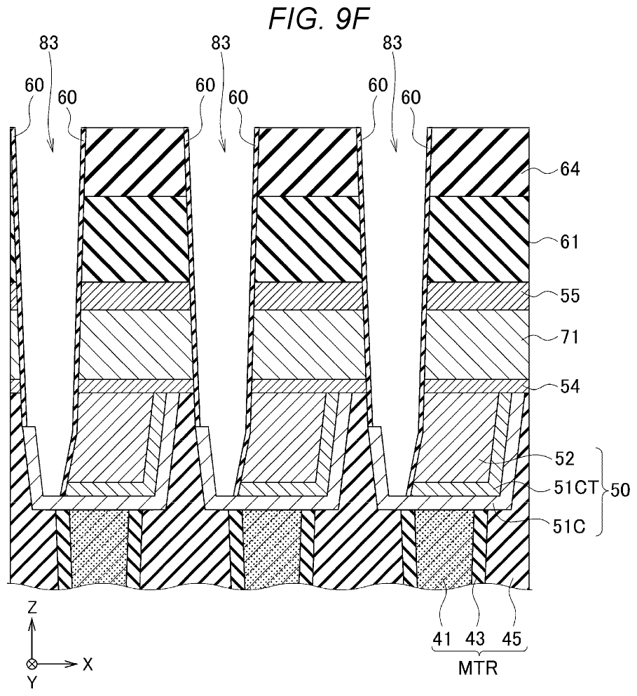

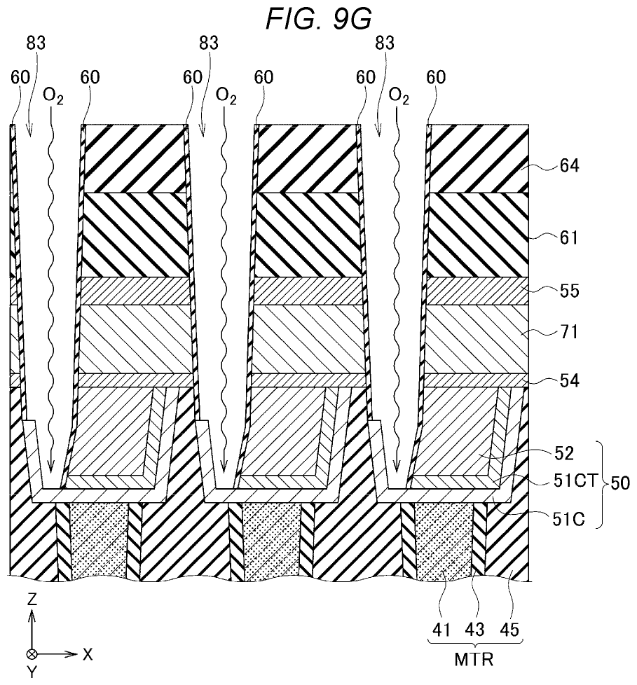

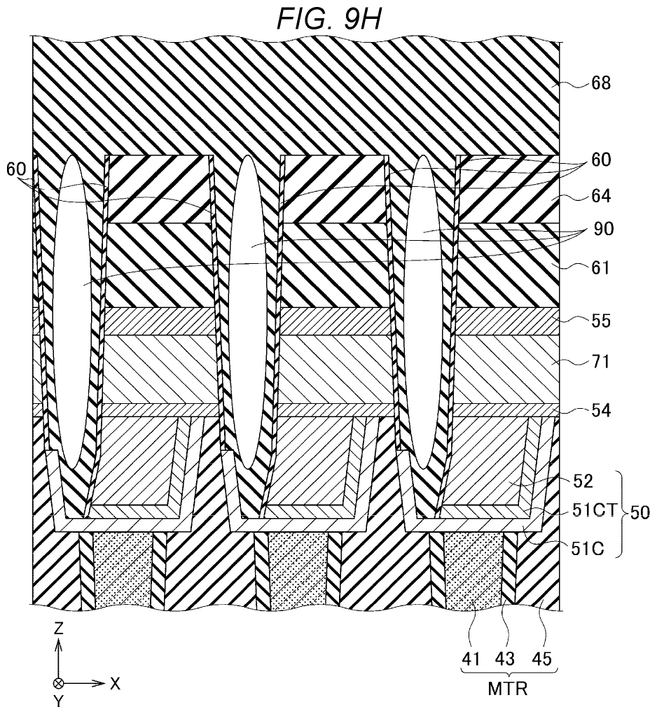

In the semiconductor device according to the second embodiment, as shown in FIG. 7, a U-shaped cup-shaped conductive oxide layer 51C is provided on the oxide semiconductor layer 41. Further, a conductive layer 51CT is provided on the conductive oxide layer 51C. The conductive oxide layer 51C, the conductive layer 51CT, and the conductive layer 52 form the second conductor 50. A bit line BL includes three layers of a main conductive layer 71, a barrier metal conductive layer 54, and a conductive layer 55. In addition, a landing pad (LP) includes three layers of a main conductive layer 52, a barrier metal conductive layer 51CT, and a conductive oxide layer 51C. In FIG. 7, an insulating layer 68, an insulating layer 64, a part of an insulating layer 60, and a part of an insulating layer 61 in the structure of FIG. 9H are omitted.

In the semiconductor device according to the second embodiment, as shown in FIG. 7, since the conductive oxide layer 51C has a U-shaped cup shape, the volume of the conductive layer 52 portion forming the landing pad (LP) is larger than that of the semiconductor device according to the first embodiment. Therefore, the contact area between the conductive layer 52 and the conductive layer 54 that form the landing pad (LP) can be increased. In addition, since the contact area between the conductive oxide layer 51C and the conductive layer 51CT can be increased, the adhesion between the conductive oxide layer 51C and the conductive layer 51CT can be enhanced. The reason why the adhesion between the conductive oxide layer 51C and the conductive layer 51CT is high is not only because the contact area is large, but also because the adhesion is increased with a contact in a U-shaped cup shape that is not a simple parallel contact.

In addition, since a mark of a lower layer can be seen through the oxide film (see FIG. 9A), a step forming process before forming the landing pad (LP) formed of the conductive oxide layer 51C, the conductive layer 51CT, and the conductive layer 52 that form the landing pad (LP) is not required.

In addition, since oxygen can be supplied to the oxide semiconductor layer 41 provided above the memory transistor MTR via the conductive oxide layer 51C after separation formation of the conductive layers 54, the conductive layers 55, and the conductive layers 71 serving as the bit lines BL, oxygen loss due to the temperature of the bit line BL forming process or the like is avoided.

In the semiconductor device according to the second embodiment, as shown in FIG. 7, the second conductor 50 includes the conductive oxide layer 51C, the conductive layer 51CT disposed on the conductive oxide layer 51C, and the conductive layer 52 disposed on the conductive layer 51CT, and has an inverted trapezoidal shape.

That is, as shown in FIGS. 7 and 8, the second conductor 50 has a circular cross-section in the XY plane, and when a diameter of the circular cross-section at an upper portion of the second conductor 50 is t1 and a diameter of the circular cross-section at a lower portion of the second conductor 50 is t3, t1>t3 is satisfied.

The second conductor 50 of the semiconductor device according to the second embodiment includes the conductive oxide layer 51C such as ITO, the conductive layer 51CT such as TiN, and the conductive layer 52 such as W, and has an inverted trapezoidal shape in which t1>t3 by being processed using CMP, dry etching, or wet etching after being embedded in the trench as shown in FIGS. 9A to 9F.

In addition, in the semiconductor device according to the second embodiment, as shown in FIGS. 7 and 8, the conductor 50 serving as the top electrode has a recessed shape in which the diameter of the conductor 50 serving as the top electrode satisfies t1>t2 in a region that is in contact with the conductive layer 54 and that is connected to the conductive layer 54 and a region that is not in contact with the conductive layer 54.

That is, when a diameter of the circular cross-section of the second conductor 50 not in contact with the conductive layer 54 is t2, the diameter t1 of the circular cross-section at the upper portion of the second conductor 50 is the diameter t1 of the circular cross-section of the second conductor 50 in contact with the conductive layer 54, and t1>t2 is satisfied.

In the conductive oxide layer 51C, a part of a region not in contact with the conductive layer 51CT is bent in the Z direction orthogonal to the X direction and the Y direction, and the conductive oxide layer 51C has a U-shaped cup shape.

### Manufacturing Method in Second Embodiment

Next, a method for manufacturing the semiconductor device according to the second embodiment will be described with reference to FIGS. 9A to 9H.

First, as shown in FIG. 9A, the insulating layer 45 is formed on the memory transistor MTR, and then the insulating layer 45 is patterned by a lithography step and a RIE or wet etching process to expose the surface of the oxide semiconductor layer 41. Here, the surface of the oxide semiconductor layer 41 is exposed at the bottom portion of a U-shaped groove 82 sandwiched by the insulating layers 45. Here, since the insulating layer 45 is a permeable film, an alignment mark (mark for performing alignment of the lithography) of a base can be visually recognized through the insulating layer 45. Therefore, it is not necessary to perform the step forming process on the base in advance in the lithography step for patterning the insulating layer 45.

Next, as shown in FIG. 9B, the conductor 50 including the conductive oxide layer 51C, the conductive layer 51CT, and the conductive layer 52 is formed across the step of the U-shaped groove 82. In the semiconductor device according to the second embodiment, since the conductor 50 including the conductive oxide layer 51C, the conductive layer 51CT, and the conductive layer 52 is embedded in the U-shaped groove 82, the possibility of peeling off each layer can be reduced as compared with simply stacking the layers in a flat structure.

Next, as shown in FIG. 9C, the surface is flattened using the CMP technique. As a result, the conductive layer 52 has a metal damascene structure and the surface thereof is flattened.

Next, as shown in FIG. 9D, the conductive layer 54, the conductive layer 71 serving as the bit line BL, the conductive layer 55, the insulating layer 61, and the insulating layer 64 are sequentially formed. Here, the conductive layer 55 is formed of, for example, TiN or the like, and the insulating layer 64 is formed of a nitride film or the like. The insulating layer 61 is a silicon oxide film or the like formed by a plasma CVD method using monosilane (SiH₄) as a material gas. The step of forming the insulating layer 64 may be omitted.

Next, as shown in FIG. 9E, the insulating layer 64, the insulating layer 61, the conductive layer 55, the conductive layer 71, the conductive layer 54, the conductive layer 52, and the conductive layer 51CT are removed by RIE or the like in the lithography step to expose a part of the surface of the U-cup-shaped conductive oxide layer 51C. Here, the conductive layers 54 are separated from each other, the conductive layers 71 are separated from each other, and the conductive layers 55 are separated from each other. Furthermore, the insulating layer 66 serving as a liner film is formed in a groove 83 formed by RIE or the like. As a result, as shown in FIG. 9E, the conductive layer 52 has an inverted trapezoidal shape, and the interconnect resistance of the conductor 50 is reduced. In addition, the contact resistance between the conductive layer 52 and the conductive layer 54 of the conductor 50 can be reduced.

Next, as shown in FIG. 9F, the lower portion of the insulating layer 66 is etched until the insulating layer 66 on the bottom portion of the groove 83 and the side wall portion in the vicinity of the bottom portion are removed to expose the conductive oxide layer 51C. As a result, a part of the surface of the conductive oxide layer 51C is exposed. With this step, when the lower portion of the insulating layer 66 is etched, the side wall of the insulating layer 66 may also be thinned and become, for example, the insulating layer 60 in this case.

Next, as shown in FIG. 9G, oxygen (O₂) is supplied to the oxide semiconductor layer 41 provided above the memory transistor MTR via the conductive oxide layer 51C in an oxygen atmosphere. At this time, since the side wall portion of the groove 83 is protected by the insulating layer 60 such as a nitride film, the conductive layer 55, the conductive layer 71, the conductive layer 54, the conductive layer 52, or the conductive layer 51CT are not affected by oxidation due to oxygen supply annealing.

Next, as shown in FIG. 9H, the insulating layer 68 is formed in the groove 83 by CVD or the like. At the time of forming the insulating layer 68, the interconnect capacitance of the bit line BL can be reduced by forming an air gap 90. The insulating layer 68 is embedded in the groove 83 after the supply of oxygen (O₂), so that oxygen (O₂) can be confined in the oxide semiconductor layer 41.

When the landing pad LP is formed by RIE processing as a method of forming the landing pad LP, W (71) is formed and then LP is subjected to lithography. At this time, since W (71) is an impermeable film, the alignment mark of the base cannot be visually recognized after the formation of W (71), and mask alignment cannot be performed. Usually, a mark step forming process is performed before forming the impermeable film such as W (71) to form a step on the base, and this step is used as the alignment mark. As a result, since the step can be visually recognized even when an impermeable film is formed, mask alignment can be performed. In the method for manufacturing the semiconductor device according to the second embodiment, the landing pad LP is formed by damascene processing. The lithography of the LP is performed before forming the impermeable W (71), and thus a hole of the LP is formed. Therefore, the mark can be visually recognized without forming the mark step, and mask alignment in lithography can be performed.

### Effects of Second Embodiment

According to the second embodiment, it is possible to provide a semiconductor device and a manufacturing method thereof, in which, with the U-shaped cup-shaped conductive oxide layer, the exposure area to the supply of oxygen can be increased, so that the supply of oxygen can be stably performed, and the decrease in reliability can be reduced.

### Third Embodiment

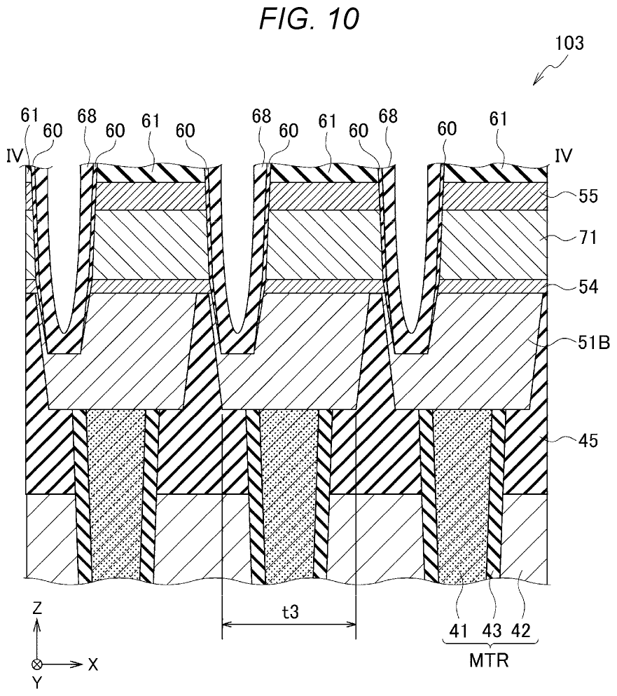

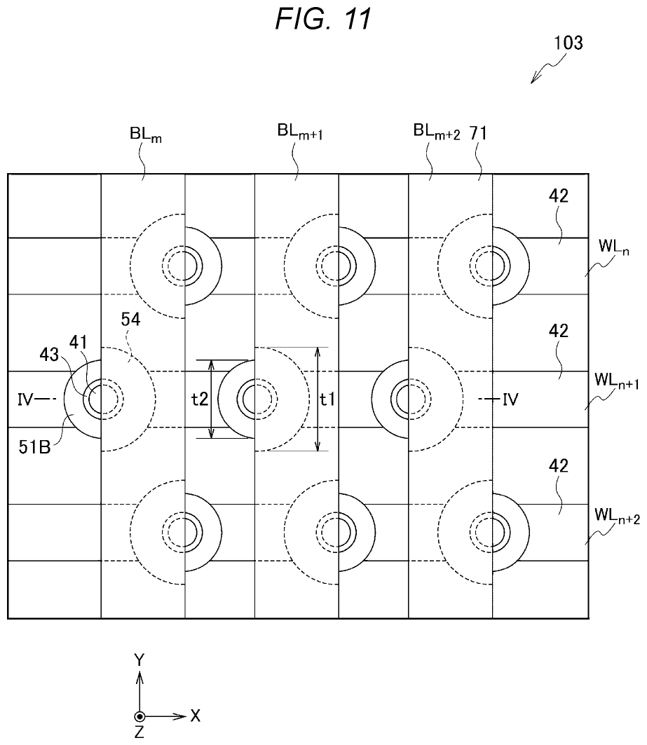

FIG. 10 is a cross-sectional view of a memory cell array 103 of the semiconductor device according to the third embodiment. FIG. 11 is a plan view of the memory cell array 103 of the semiconductor device according to the third embodiment. FIG. 10 shows a cross-sectional structure taken along the line IV-IV of FIG. 11.

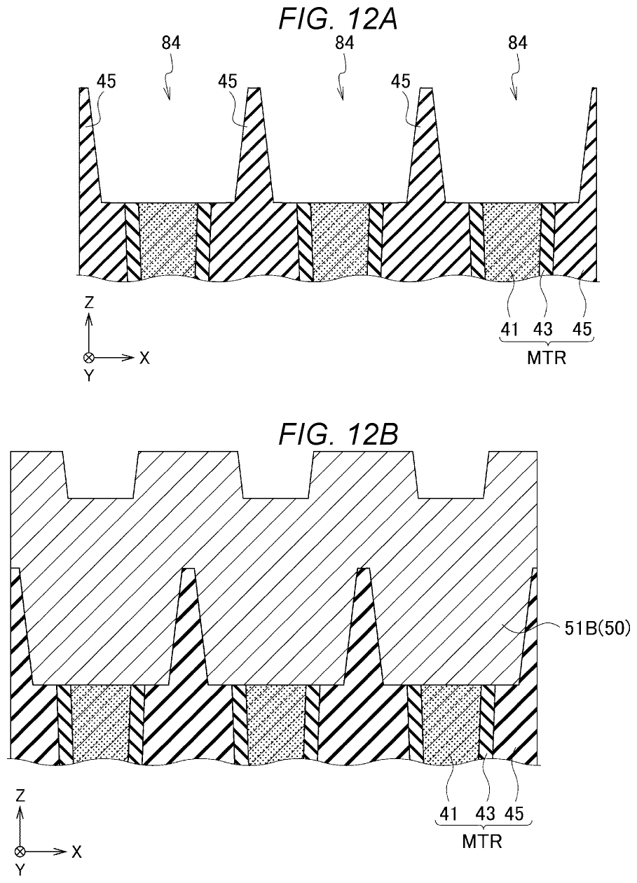

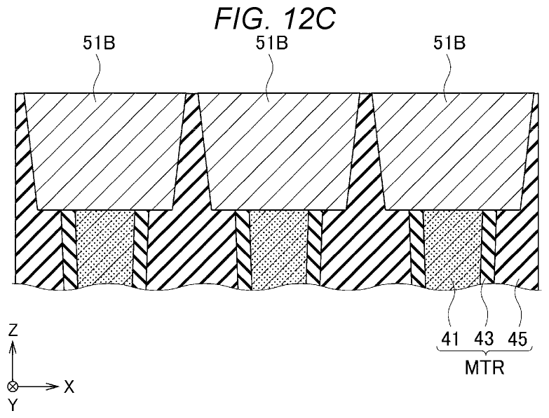

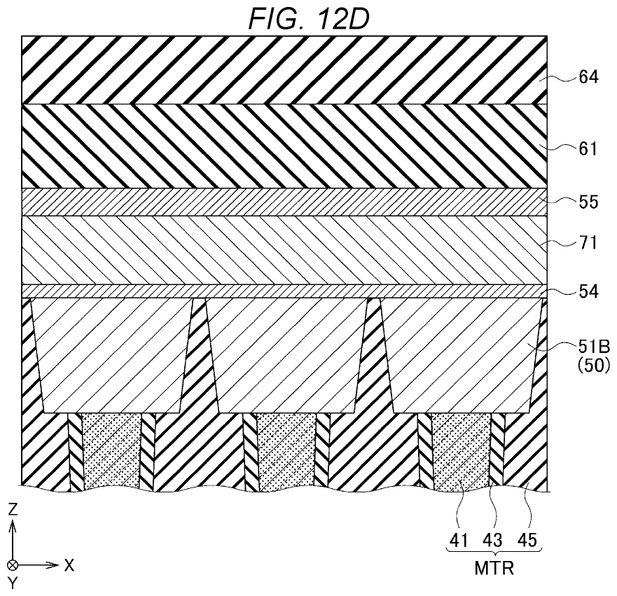

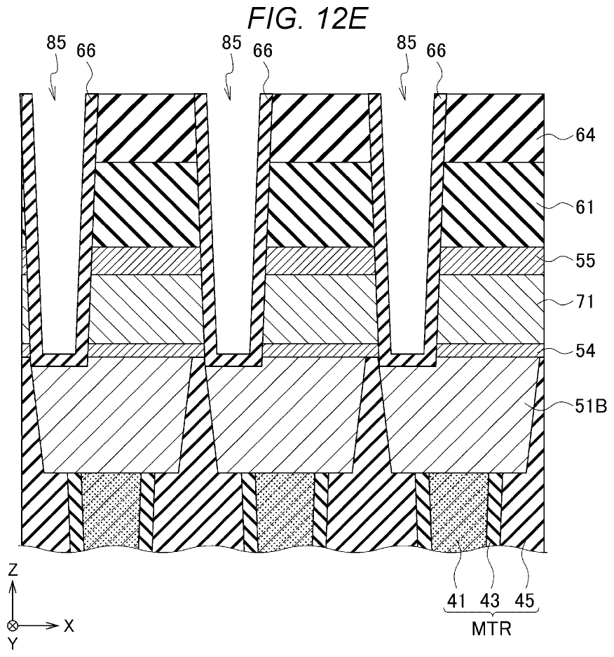

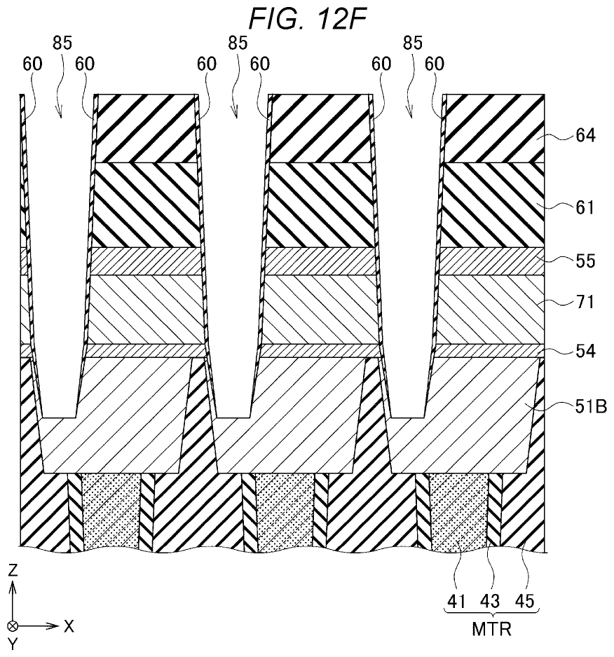

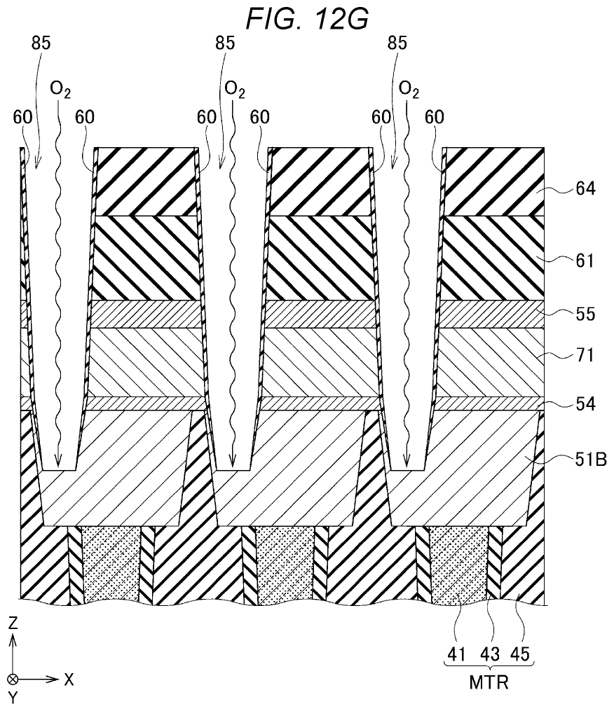

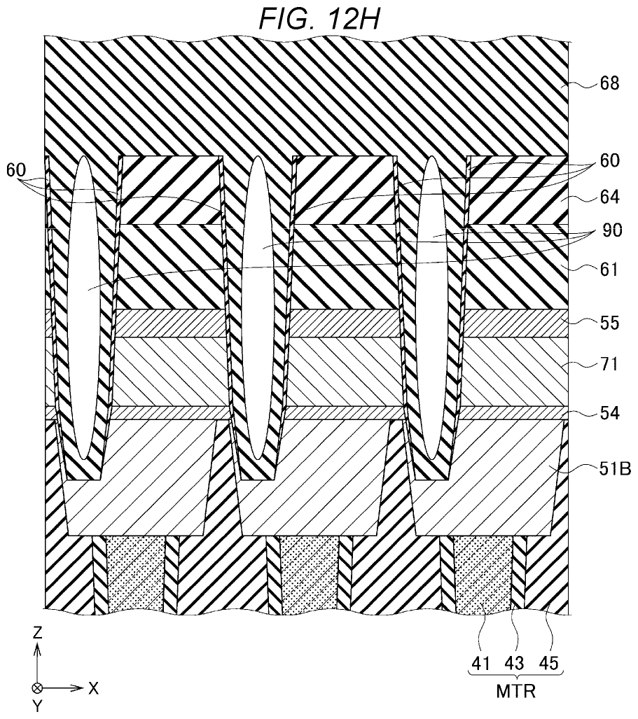

As in the structure shown in FIG. 3, the semiconductor device according to the third embodiment includes the first conductor 30, the second conductor 50, the oxide semiconductor layer 41 provided between the first conductor 30 and the second conductor 50 and extending in the Y direction, the conductive layer 42 extending in the X direction intersecting the Y direction and surrounding the oxide semiconductor layer 41, and the insulating film 43 provided between the oxide semiconductor layer 41 and the conductive layer 42 and being an oxide film in contact with the conductive layer 42. A bit line BL includes three layers of the main conductive layer 71, the barrier metal conductive layer 54, and the conductive layer 55. In addition, a landing pad (LP) is formed of a single layer of a conductive oxide layer 51B. In FIG. 10, an insulating layer 68, an insulating layer 64, a part of an insulating layer 60, and a part of an insulating layer 61 in the structure of FIG. 12H are omitted.

In the semiconductor device according to the third embodiment, as shown in FIG. 10, the bulk-shaped conductive oxide layer 51B is provided on the oxide semiconductor layer 41. Further, the conductive oxide layer 51B itself forms the conductor 50. That is, by forming all the landing pads (LP) into the conductive oxide layer 51B, the exposure area to the supply of oxygen can be increased, and oxygen can be supplied to the bulk center of the conductive oxide layer 51B.

In the semiconductor device according to the third embodiment, as shown in FIG. 10, since oxygen can be supplied from the side wall of the thick conductive oxide layer 51B, oxygen molecules (atoms) can permeate to the deep central portion of the conductive oxide layer 51B bulk. The width of the passage of oxygen in the conductive oxide layer 51B from the oxygen supply area to an IGZO channel of the oxide semiconductor layer 41 is wide, and oxygen can be more efficiently supplied to the oxide semiconductor layer 41.

In addition, since a mark of the lower layer can be seen through the oxide film (66: see FIG. 12E), the step forming process before the formation of the landing pad (LP) is not required.

In addition, since oxygen can be supplied to the oxide semiconductor layer 41 provided above the memory transistor MTR via the conductive oxide layer 51B after the separation formation between the conductive layers 54, between the conductive layers 71, and between the conductive layers 55, oxygen loss due to the temperature of the bit line BL forming process or the like is avoided.

In the semiconductor device according to the third embodiment, as shown in FIG. 10, the second conductor 50 includes a single conductive oxide layer 51B and has an inverted trapezoidal shape.

That is, as shown in FIGS. 10 and 11, the second conductor 50 has a circular cross-section in the XY plane, and when a diameter of the circular cross-section at an upper portion of the second conductor 50 is t1 and a diameter of the circular cross-section at a lower portion of the second conductor 50 is t3, t1>t3 is satisfied.

The second conductor 50 of the semiconductor device according to the third embodiment includes the conductive oxide layer 51B such as ITO, and has an inverted trapezoidal shape in which t1>t3 by being processed using CMP, dry etching, or wet etching after being embedded in the trench as shown in FIGS. 12A to 12F.

In addition, in the semiconductor device according to the third embodiment, as shown in FIGS. 10 and 11, the conductive oxide layer 51B has a recessed shape in which the diameter of the conductor 50 serving as the top electrode satisfies t1>t2 in a region in contact with the conductive layer 54 and a region not in contact with the conductive layer 54.

That is, when a diameter of the circular cross-section of the second conductor 50 not in contact with the conductive layer 54 is t2, the diameter t1 of the circular cross-section at the upper portion of the second conductor 50 is the diameter t1 of the circular cross-section of the second conductor 50 in contact with the conductive layer 54, and t1>t2 is satisfied.

### Manufacturing Method in Third Embodiment

Next, a method for manufacturing the semiconductor device according to the third embodiment will be described with reference to FIGS. 12A to 12H.

First, as shown in FIG. 12A, an insulating layer 45 is formed on the memory transistor MTR, and then the insulating layer 45 is patterned by a lithography step and a RIE or wet etching process to expose the surface of the oxide semiconductor layer 41. Here, the surface of the oxide semiconductor layer 41 is exposed at the bottom portion of the U-shaped groove 84 sandwiched by the insulating layers 45. Here, since the insulating layer 45 is a permeable film, an alignment mark (mark for performing alignment of the lithography) of a base can be visually recognized through the insulating layer 45. Therefore, it is not necessary to perform the step forming process on the base in advance in the lithography step for patterning the insulating layer 45.

Next, as shown in FIG. 12B, the conductor 50 including the conductive oxide layer 51C, the conductive layer 51CT, and the conductive layer 52 is formed across the step of the U-shaped groove 84. In the semiconductor device according to the third embodiment, since the conductor 50 including the conductive oxide layer 51C, the conductive layer 51CT, and the conductive layer 52 is embedded in the U-shaped groove 84, the possibility of peeling off each layer can be reduced as compared with simply stacking the layers in a flat structure.

Next, as shown in FIG. 12C, the surface is flattened using the CMP technique. The surface is flattened using the CMP technique. As a result, the conductive layer 52 has a metal damascene structure and the surface thereof is flattened.

Next, as shown in FIG. 12D, the conductive layer 54, the conductive layer 71, the conductive layer 55, the insulating layer 61, and the insulating layer 64 are sequentially formed. Here, the conductive layer 55 is formed of, for example, TiN or the like, and the insulating layer 64 is formed of a nitride film or the like. The insulating layer 61 is a silicon oxide film or the like formed by a plasma CVD method using monosilane (SiH₄) as a material gas. The step of forming the insulating layer 64 may be omitted.

Next, as shown in FIG. 12E, the insulating layer 64, the insulating layer 61, the conductive layer 55, the conductive layer 71, and the conductive layer 54 are removed by RIE or the like in the lithography step to expose a part of the surface of the conductive oxide layer 51B. Here, the conductive layers 54 are separated from each other, the conductive layers 71 are separated from each other, and the conductive layers 55 are separated from each other. Furthermore, the insulating layer 66 serving as a liner film is formed in the groove 85 formed by RIE or the like. As a result, as shown in FIG. 12E, the conductive oxide layer 51B has an inverted trapezoidal shape, and the interconnect resistance of the conductor 50 is reduced. In addition, the contact resistance between the conductive oxide layer 51B and the conductive layer 54 of the conductor 50 can be reduced.

Next, as shown in FIG. 12F, the lower portion of the insulating layer 66 is etched until the insulating layer 66 on the bottom portion of the groove 85 and the side wall portion in the vicinity of the bottom portion are removed to expose the conductive oxide layer 51B. As a result, a part of the surface of the conductive oxide layer 51B is exposed. With this step, when the lower portion of the insulating layer 66 is etched, the side wall of the insulating layer 66 may also be thinned and become, for example, the insulating layer 60 in this case.

Next, as shown in FIG. 12G, oxygen (O₂) is supplied to the oxide semiconductor layer 41 provided above the memory transistor MTR via the conductive oxide layer 51B in an oxygen atmosphere. At this time, since the side wall portion of the groove 85 is protected by the insulating layer 60 such as a nitride film, the conductive layer 55, the conductive layer 71, the conductive layer 54, the conductive layer 52, or the conductive oxide layer 51B are not affected by oxidation due to oxygen supply annealing.

Next, as shown in FIG. 12H, the insulating layer 68 is formed in the groove 85 by CVD or the like. At the time of forming the insulating layer 68, the interconnect capacitance of the bit line BL can be reduced by forming an air gap 90. The insulating layer 68 is embedded in the groove 85 after the supply of oxygen (O₂), so that oxygen (O₂) can be confined in the oxide semiconductor layer 41.

### Effects of Third Embodiment

According to the third embodiment, it is possible to provide a semiconductor device and a manufacturing method thereof, in which, by forming all the landing pads (LP) into the conductive oxide layer, the exposure area to the supply oxygen can be increased, so that oxygen can be supplied to the bulk center of the conductive oxide layer, and the width of the passage of oxygen in the conductive oxide layer can be made wide. As a result, the oxygen supply to the oxide semiconductor layer can be performed more efficiently, and a decrease in reliability is reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor substrate;
a memory capacitor provided on the semiconductor substrate;
a first conductor provided above the memory capacitor and extending in a first direction;
a second conductor provided above the first conductor and extending in the first direction;
an oxide semiconductor layer provided between the first conductor and the second conductor and extending in the first direction;
a conductive oxide layer between the second conductor and the oxide semiconductor layer;
a first conductive layer between the conductive oxide layer and the second conductor; and
a first insulating layer in contact with the conductive oxide layer, wherein a portion of the conductive oxide layer is between and aligned with the first insulating layer and the oxide semiconductor layer in the first direction.

2. The semiconductor device according to claim 1, further comprising:
a second conductive layer extending in a second direction intersecting the first direction and surrounding the oxide semiconductor layer; and
an insulating film provided between the oxide semiconductor layer and the second conductive layer and in contact with the oxide semiconductor layer and the second conductive layer.

3. The semiconductor device according to claim 2,
wherein the insulating film contains at least one element selected from the group consisting of silicon (Si), aluminum (Al), hafnium (Hf), zirconium (Zr), lanthanum (La), niobium (Nb), yttrium (Y), tantalum (Ta), vanadium (V), and magnesium (Mg), and oxygen.

4. The semiconductor device according to claim 1, wherein the semiconductor substrate includes a circuit having a complementary field effect transistor.

5. The semiconductor device according to claim 1, wherein the conductive oxide layer contains a metal oxide of indium-tin-oxide (ITO).

6. The semiconductor device according to claim 1, further comprising:
a second insulating layer in contact with a first side wall of the first conductive layer, and separating the first conductive layer from the first insulating layer.

7. The semiconductor device according to claim 6, wherein the second insulating layer is not in contact with a second side wall of the first conductive layer that is on an opposite side of the first conductive layer from the first side wall in the second direction.

8. The semiconductor device according to claim 1, further comprising:
a second conductive layer between the conductive oxide layer and the second conductor.

9. The semiconductor device according to claim 1, wherein the oxide semiconductor layer contains indium oxide and gallium oxide, indium oxide and zinc oxide, or indium oxide and tin oxide.

10. The semiconductor device according to claim 1, wherein the first conductive layer contains at least one material selected from the group consisting of tungsten (W), titanium (Ti), titanium nitride (TiN), molybdenum (Mo), cobalt (Co), and ruthenium (Ru).

11. The semiconductor device according to claim 1, wherein the first insulating layer contains at least one material selected from the group consisting of aluminum oxide (AlOx), zirconium oxide (ZrOx), silicon nitride (SiNx), and silicon oxide (SiOx).

12. A semiconductor device comprising:
a semiconductor substrate;
a memory capacitor provided on the semiconductor substrate;
a first conductor provided above the memory capacitor and extending in a first direction;
a second conductor provided above the first conductor and extending in the first direction, the second conductor including a conductive oxide layer, a first conductive layer disposed on the conductive oxide layer, and a second conductive layer disposed on the first conductive layer, and having an inverted trapezoidal shape when viewed in the first direction;
an oxide semiconductor layer provided between the first conductor and the conductive oxide layer of the second conductor and extending in the first direction; and
a first insulating layer in contact with the conductive oxide layer and having a portion that is between the conductive oxide layer and the first and second conductive layers in a second direction intersecting the first direction.

13. The semiconductor device according to claim 12, further comprising:
a third conductive layer extending in the second direction and surrounding the oxide semiconductor layer; and
an insulating film provided between the oxide semiconductor layer and the third conductive layer and in contact with the oxide semiconductor layer and the third conductive layer.

14. The semiconductor device according to claim 12, wherein the second conductor has a circular cross section in a plane parallel to the first direction, and a diameter of the circular cross section at an upper portion of the second conductor is greater than a diameter of the circular cross section at a lower portion of the second conductor.

15. The semiconductor device according to claim 14, further comprising:
a third conductor provided on the second conductor and extending in the first direction,
wherein a diameter of the circular cross section of the second conductor not in contact with the third conductor is less than a diameter of the circular cross section at the upper portion of the second conductor that is in contact with the third conductor.

16. The semiconductor device according to claim 14, wherein a part of the conductive oxide layer not in contact with the first conductive layer is bent in a third direction orthogonal to the first direction and the second direction to have a U-shaped cup shape.

17. A semiconductor device comprising:
a semiconductor substrate;
a memory capacitor provided on the semiconductor substrate;
a first conductor provided above the memory capacitor and extending in a first direction;
a second conductor provided above the first conductor and extending in the first direction, the second conductor including a conductive oxide layer and having an inverted trapezoidal shape when viewed in the first direction;
an oxide semiconductor layer provided between the first conductor and the conductive oxide layer of the second conductor and extending in the first direction; and
a first insulating layer in contact with the second conductor and having a portion that extends into the second conductor so that a bottom surface of the first insulating layer is below an upper surface of the second conductor.

18. The semiconductor device according to claim 17, further comprising:
a third conductive layer extending in the second direction and surrounding the oxide semiconductor layer; and
an insulating film provided between the oxide semiconductor layer and the third conductive layer and in contact with the oxide semiconductor layer and the third conductive layer.

19. The semiconductor device according to claim 17, wherein the second conductor has a circular cross section in a plane parallel to the first direction, and a diameter of the circular cross section at an upper portion of the second conductor is greater than a diameter of the circular cross section at a lower portion of the second conductor.

20. The semiconductor device according to claim 19, further comprising:
a third conductor provided on the second conductor and extending in the first direction,
wherein a diameter of the circular cross section of the second conductor not in contact with the third conductor is less than a diameter of the circular cross section at the upper portion of the second conductor that is in contact with the third conductor.
